(19) United States
(12) Patent Application Publication
(10) Pub. No.: US 2004/0061175 A1
(43) Pub. Date: Apr. 1, 2004

(54) Full depletion SOI-MOS transistor

(76) Inventor: Koichi Fukuda, Tokyo (JP)

Correspondence Address: VOLENTINE FRANCOS, P.L.L.C., Suite 150, 12200 Sunrise Valley Drive, Reston, VA, 20191, US

(21) Appl. No.: 10/635,006

(22) Filed: Aug. 6, 2003

(30) Foreign Application Priority Data
Aug. 19, 2002 (JP) 238169/2002

(51) Int. Cl. H01L 27/01

(52) U.S. Cl. 257/347

(57) ABSTRACT

A full depletion SOI-MOS transistor includes a substrate, a buried oxide layer, a thin silicon layer, an isolation layer, a gate insulation layer, a gate electrode and a polysilicon layer. The buried oxide layer is formed on a main surface of the substrate. The thin silicon layer is formed on the buried oxide layer and includes a channel region and a source/drain region. The isolation layer is formed on the buried oxide layer and surrounds the thin silicon layer. A gate insulation layer and gate electrode are formed on the channel region of the thin silicon layer. The polysilicon layer is formed on the source/drain region of the thin silicon layer.

### BACKGROUND OF THE INVENTION

This invention relates to a full depletion SOI-MOS transistor and to a method of fabricating the same.

A full depletion SOI-MOS transistor has advantages as described below compared with an ordinary bulk MOS transistor fabricated on a Si substrate.

Namely, (1) it has good sub-threshold characteristics enabling Vt to be lowered and, hence, to obtain a larger on-current at the same voltage, and (2) it has a small junction capacity that serves as a load and a high operation speed of a circuit can be expected.

In the full depletion SOI-MOS transistor, it is one of the features in that a depletion layer in the SOI layer is already reaching the BOX layer in a state where the gate potential has been turned off. The BOX layer suppresses the extension of the depletion layer, whereby a current sharply increases with a rise in the gate and good sub-threshold characteristics are exhibited. The BOX layer further suppresses the extension of the depletion layer from the drain region and, hence, suppresses a short-channel effect that becomes a problem in fine elements.

However, the short-channel effect becomes more serious as the gate becomes more fine, and it becomes necessary to reduce the thickness of the SOI layer.

In order to decrease the thickness of the SOI layer, there has been proposed an elevated-source/drain technology. Namely, Si grows selectively and epitaxially on the source/drain regions whereby the thickness of the source/drain portions increases to decrease the resistance.

This technology, however, is still accompanied by problems concerning throughput of epitaxial growth and maintaining Si epitaxial selection, and mass-production has not yet been realized.

Namely, an extended period of time is required for forming the Si layer by the epitaxial growth causing a decrease in the throughput.

If the temperature is elevated during the epitaxial growth in an attempt to increase the throughput, then, the thin SOI layer aggregates.

Thus, limitation is imposed on the thin SOI film when it is attempted to elevate the temperature.

### SUMMARY OF THE INVENTION

The present invention may provide a full depletion SOI-MOS transistor which improves throughput, suppresses the short-channel effect and gives a low source-drain resistance.

A full depletion SOI-MOS transistor according to the present invention includes a substrate, a buried oxide layer, a thin silicon layer, an isolation layer, a gate insulation layer, a gate electrode and a polysilicon layer. The buried oxide layer is formed on a main surface of the substrate. The thin silicon layer is formed on the buried oxide layer and includes a channel region and a source/drain region. The isolation layer is formed on the buried oxide layer and surrounds the thin silicon layer. A gate insulation layer and gate electrode are formed on the channel region of the thin silicon layer. The polysilicon layer is formed on the source/drain region of the thin silicon layer.

### BRIEF DESCRIPTION OF THE DRAWINGS

FIG. 1 is a sectional view schematically illustrating a full depletion SOI-MOS transistor of the invention;

FIG. 2 is a sectional view schematically illustrating the full depletion SOI-MOS transistor of FIG. 1 that is transformed into a silicide;

FIGS. 3A to 3C are sectional views schematically illustrating the steps in a method of fabricating the full depletion SOI-MOS transistor according to an embodiment of the invention;

FIGS. 4A to 4D are sectional views schematically illustrating the steps in the method of fabricating the full depletion SOI-MOS transistor according to an embodiment of the invention;

FIGS. 5A to 5D are sectional views schematically illustrating the steps in the method of fabricating the full depletion SOI-MOS transistor according to an embodiment of the invention;

FIGS. 6A to 6D are sectional views schematically illustrating the steps in the method of fabricating the full depletion SOI-MOS transistor according to an embodiment of the invention;

FIGS. 7A to 7C are sectional views schematically illustrating the steps in the method of fabricating the full depletion SOI-MOS transistor according to an embodiment of the invention;

FIGS. 8A to 8C are sectional views schematically illustrating the steps in the method of fabricating the full depletion SOI-MOS transistor according to an embodiment of the invention;

FIGS. 9A and 9B are sectional views schematically illustrating the steps in the method of fabricating the full depletion SOI-MOS transistor according to an embodiment of the invention;

FIGS. 10A to 10C are sectional views schematically illustrating the steps in the method of fabricating the full depletion SOI-MOS transistor according to an embodiment of the invention;

FIGS. 11A to 11C are sectional views schematically illustrating the steps in the method of fabricating the full depletion SOI-MOS transistor according to an embodiment of the invention;

FIGS. 12A to 12C are sectional views schematically illustrating the steps in the method of fabricating the full depletion SOI-MOS transistor according to an embodiment of the invention; and

FIGS. 13A to 13C are sectional views schematically illustrating the steps in the method of fabricating the full depletion SOI-MOS transistor according to an embodiment of the invention.

### DETAILED DESCRIPTION OF THE INVENTION

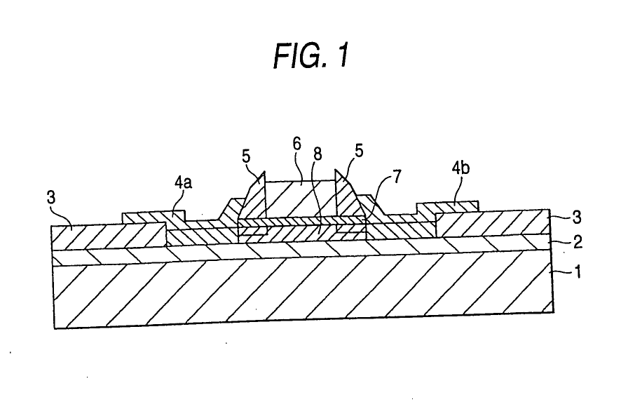

In the full depletion SOI-MOS transistor of the present invention as shown in FIG. 1, a SOI layer 8 and a gate electrode 6 are successively formed on a semiconductor substrate (preferably, SOI substrate) 1 via a BOX layer 2, and source/drain portions (source portion 4a and drain portion 4b) are formed by the deposition of polysilicon on the regions by the side of the SOI layer 8, the thickness of the SOI layer 8 being smaller than the thickness of the source/drain portions.

By forming the source/drain portions by using polysilicon, mobility of electrons is enhanced, whereby the source-drain resistance decreases and the on-current increases. It is considered that the above effect is exhibited to a striking degree since polysilicon shows higher mobility than amorphous silicon or the like silicon.

Further, a gate oxide film 7 is formed between the SOI layer 8 and the gate electrode 6, and side walls 5 are formed by the sides of the gate electrode 6 to prevent the contact with the source/drain portions. Isolation oxide films 3 are formed on the outer sides of the source/drain portions for isolating the elements.

Here, “SOI” is an abbreviation for “silicon on insulator” and, usually, stands for a semiconductor substrate having a thin silicon single crystalline layer formed on an insulating film or stands for a device formed on the substrate. When a MOS transistor is formed by using SOI, there is realized a low-power device improving characteristics, decreasing parasitic capacitance and operating on a low voltage.

In this specification, therefore, the “SOI” layer stands for a thin silicon film formed on an insulating film of the semiconductor substrate.

Upon forming the SOI layer in the full depletion type, further, it is allowed to simultaneously lower the voltage and the load capacity in contrast with those of the partial depletion type.

The SOI layer has a thickness smaller than that of the source/drain portions. The SOI layer having a decreased thickness solves the problem of short-channel effect that stems from fine gate electrodes.

The above effect appears conspicuously when the thickness of the SOI layer is not larger than about 35 nm though it may vary depending upon the conditions.

It is desired that the thickness of the SOI layer is from 20 to 80% the thickness of the source/drain portions by taking into consideration a relationship between the short-channel effect and the source-drain resistance.

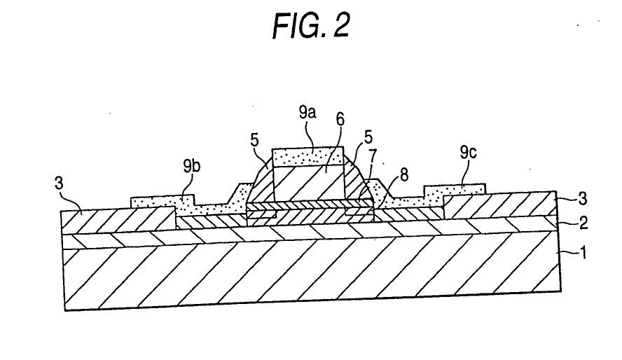

It is further desired that the source electrode and drain electrode in the source/drain portions, and the gate electrodes have been transformed into silicides as shown in FIG. 2 (9a, 9b, 9c in FIG. 2). Formation of the silicides further lowers the source-drain resistance.

The full depletion SOI-MOS transistor of the invention was described above with reference to FIGS. 1 and 2. The invention, however, is in no way limited to the above constitution only but can be varied in a variety of ways based on a known knowledge.

For example, the gate electrode material is preferably made of polysilicon. Depending upon the use, however, there may be used an electrode having a dissimilar work function differential, such as SiGe to control the threshold value.

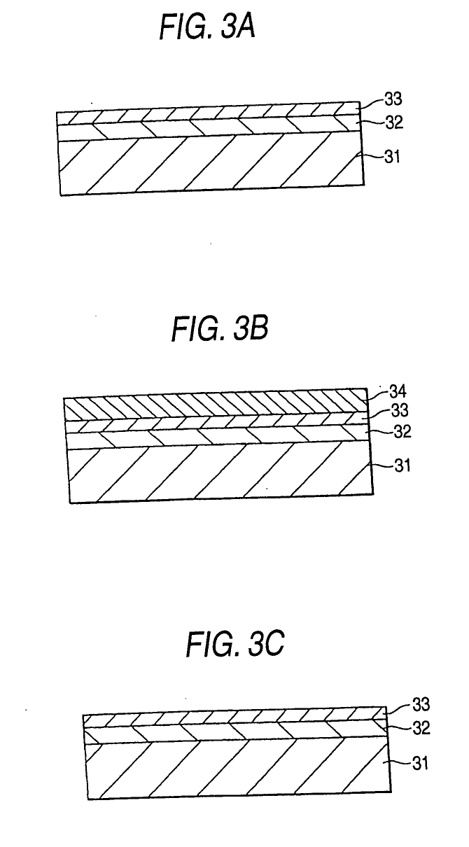

A method of fabricating the full depletion SOI-MOS transistor of the invention will now be described with reference to FIGS. 3 to 13.

First, a SOI substrate (FIG. 3A) has a BOX layer 32 and an SOI layer 33 successively formed on a Si substrate 31, and wherein the SOI layer 33 is oxidized (FIG. 3B) to form an oxide film 34 on the surface thereof. It is desired that the degree of oxidation be so adjusted that the SOI layer 33 has a thickness of from 10 to 40 nm (preferably, 10 to 30 nm). Then, as shown in FIG. 3C, the oxide film 34 is removed. Thus, there is fabricated the SOI substrate having the SOI layer 33 of a desired thickness.

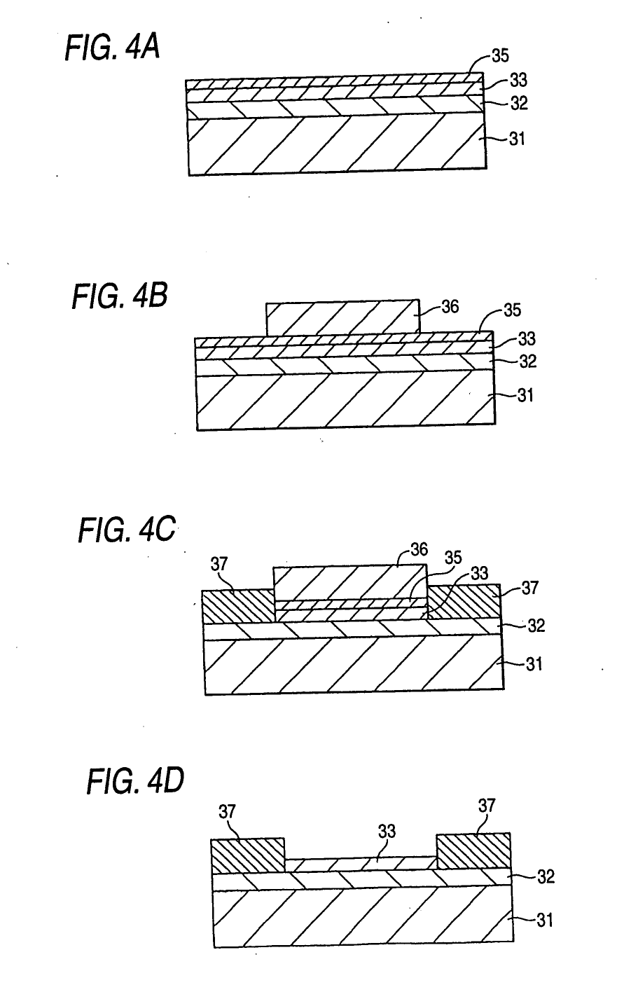

The surface of the SOI layer 33 is subjected to a pad oxidation treatment to form an oxide film 35 as shown in FIG. 4A. Then, a nitride film 36 is formed on a portion corresponding to the gate portion (portion where the gate electrode is formed) (FIG. 4B). By using the nitride film 36 as a mask, a LOCOS oxidation treatment is carried out (FIG. 4C). Due to this treatment, only a portion without the nitride film 36 is oxidized, whereby the thickness of the oxide film increases thereby to form an isolation oxide film 37 that connects to the BOX layer 32. Thereafter, the nitride film 36 is removed to form the SOI layer 33 isolated for each of the transistors.

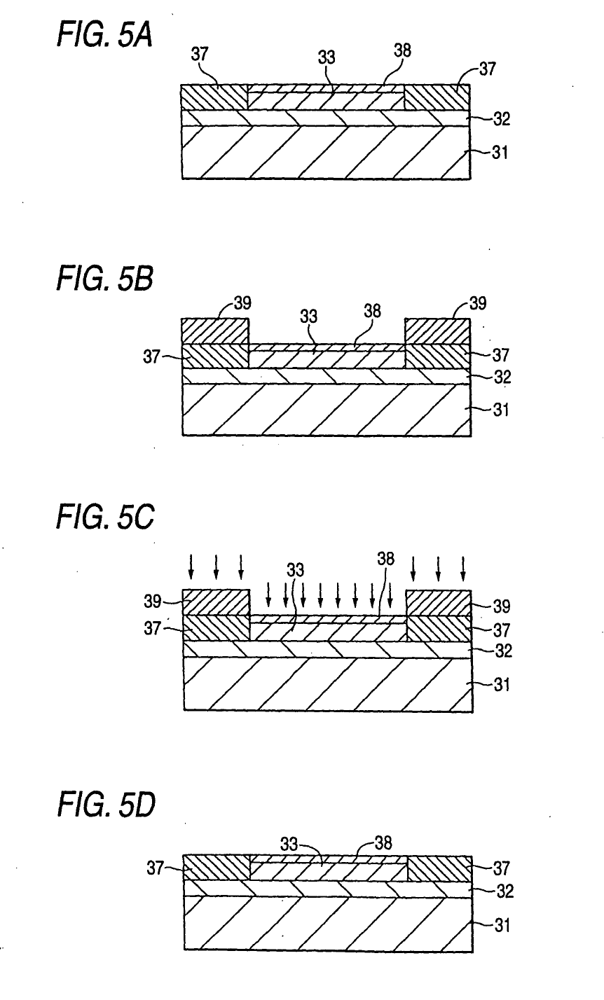

Referring to FIG. 5A, the SOI layer 33 is subjected to the gate oxidation to form a gate oxide film 38. There are, then, successively conducted an implantation-window photolithography for controlling the threshold value (FIG. 5B), ion injection for controlling the threshold voltage after a resist 39 is formed (FIG. 5C) and the removal of resist (FIG. 5D).

In the implantation-window photolithography for controlling the threshold value and in the implantation for controlling the threshold voltage, the conditions such as kinds of impurities are suitably set depending upon PMOS or NMOS.

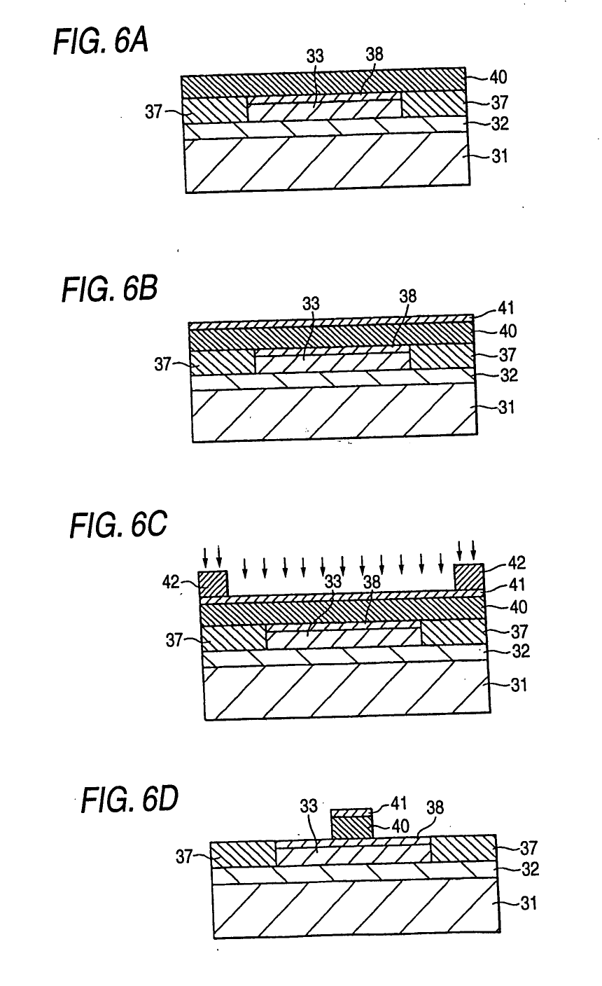

Polysilicon is deposited to form a gate electrode on the oxide films (isolation oxide film 37 and gate oxide film 38) from which the resist has been removed to thereby form a polysilicon layer 40 (polysilicon layer (A)) (FIG. 6A). For isolation from polysilicon that forms the gate electrode, an oxide film 41 of SiO₂ is formed on the polysilicon layer 40 (FIG. 6B).

The oxide film 41 must have a thickness very larger than the thickness of the gate oxide film 38 so will not to be peeled off together with the gate oxide film when the side wall etching is conducted as will be described later. Concretely speaking, its thickness is desirably 1 to 5 times as large as that of the gate oxide film 38.

Next, the gate implantation photoetching (opening in the gate impurity ion injection region) and gate implantation (FIG. 6C) are conducted, the gate is patterned, and the polysilicon layer 40 forming the oxide film 41 on the surface thereof is formed on the gate region (FIG. 6D).

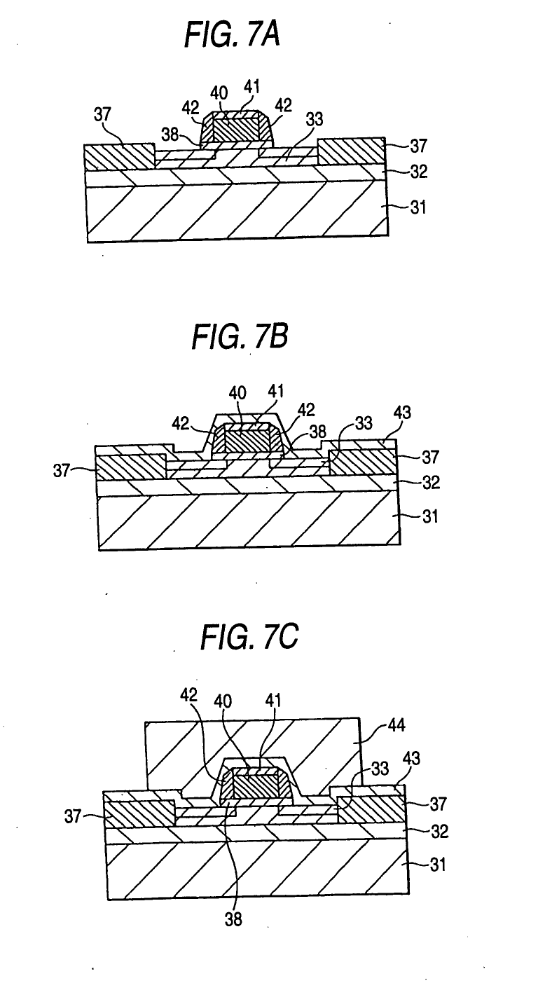

Referring to FIG. 7A, side walls 42 of a silicon nitride film are formed on the side surfaces of the polysilicon layer 40. Then, polysilicon is deposited on the whole surface to form source/drain portions thereby to form a polysilicon layer 43 (polysilicon layer (B)) (FIG. 7B).

In the present invention, the polysilicon can be deposited by the CVD method. Concrete conditions of the CVD method consist of about 620° C., about 0.2 Torr (26.6 Pa) using an SiH₄ gas.

After the polysilicon layer 43 is formed, a resist 44 is formed. Then, undesired polysilicon on the isolation oxide film 37 is removed by patterning based on the photoetching (photolithography and etching step) (FIG. 7C).

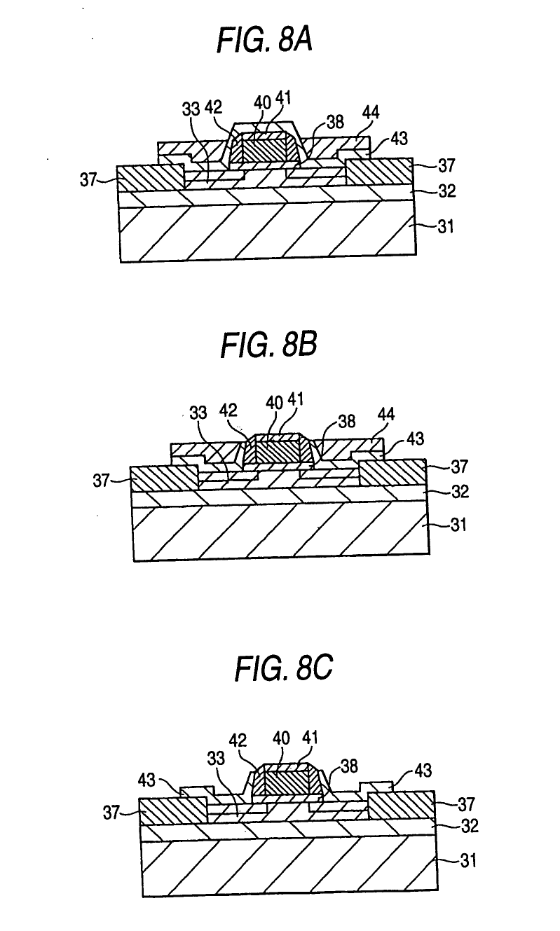

Next, the height of the resist 44 is lowered by the resist etching to expose part of the gate portion (FIG. 8A). In order to prevent the occurrence of a capacity between the polysilicon of gate and the polysilicon deposited on the whole surface, the distance between them must be increased as large as possible.

The amount for exposing part of the gate portion varies depending upon the thickness of the polysilicon layer and other setting conditions but is, desirably, not smaller than one-half the height of the gate. The upper limit is about 20 nm from the surface of the polysilicon layer 43 in parallel with the semiconductor substrate 31 in the source/drain portions.

The oxide film 41 has been formed on the polysilicon layer 40 and, hence, the polysilicon that serves as the gate electrode is not etched in excess of a predetermined range. It is therefore allowed to set the height of the gate electrode within a desired range maintaining good controllability.

Polysilicon of the polysilicon layer 43 exposed from the resist 44 is removed by etching in a state where the oxide film 41 is formed on the polysilicon layer 40 (FIG. 8B). Thereafter, the resist 44 remaining on the polysilicon layer 43 is removed (FIG. 8C).

In this invention, polysilicon of the polysilicon layer 43 is etched being divided into two times (FIG. 7C and FIG. 8B). This is because the etching in FIG. 8B is conducted under severer etching conditions concerning selectivity and the like than those of the etching in FIG. 7C. That is, by dividing the etching into two times, the etching conditions can be set more finely in FIG. 8B.

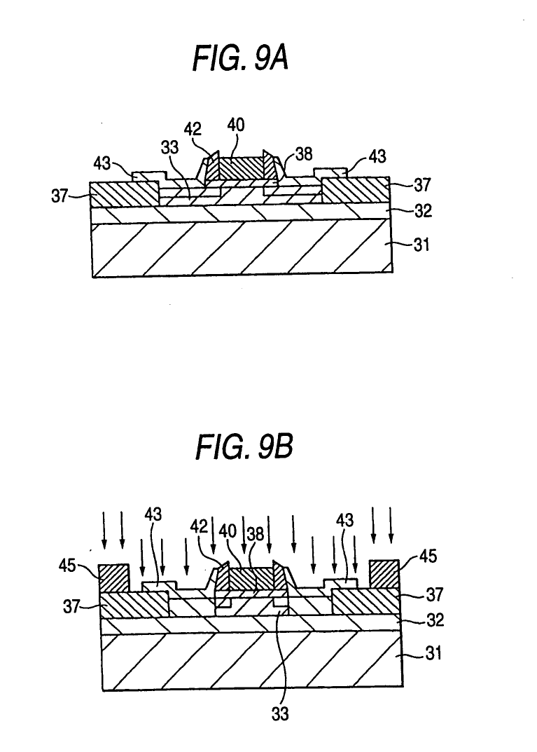

After the resist 44 has been removed, the oxide film 41 on the gate is removed by etching as shown in FIG. 9A.

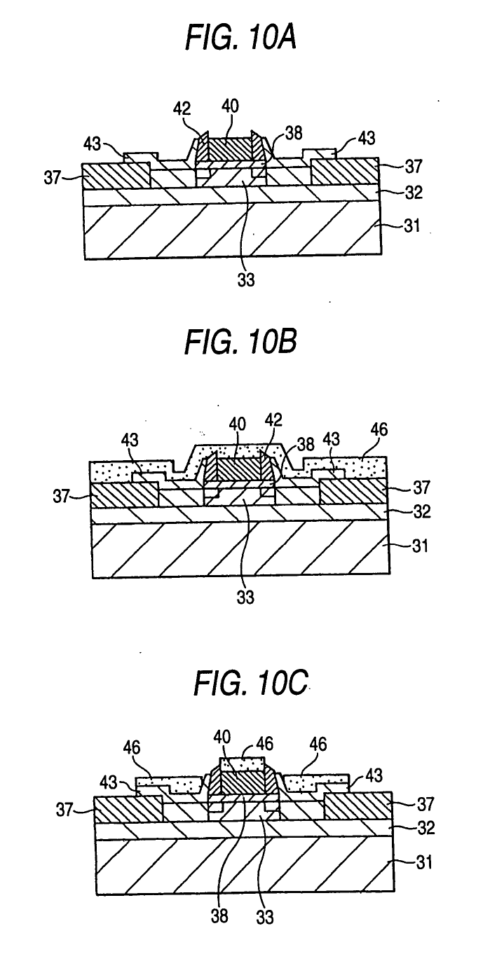

Upon effecting the etching, polysilicon is finally deposited on the source/drain portions only. Then, a resist 45 is formed, the source/drain implantation is conducted (FIG. 9B) to thereby effect the active RTA (FIG. 10A).

The active RTA may, as required, be followed by the transformation into a silicide. Concretely speaking, as shown in FIG. 10B, Co is precipitated on the surface followed by the transformation into the silicide (as designated at 46) to selectively etch Co (FIG. 10C).

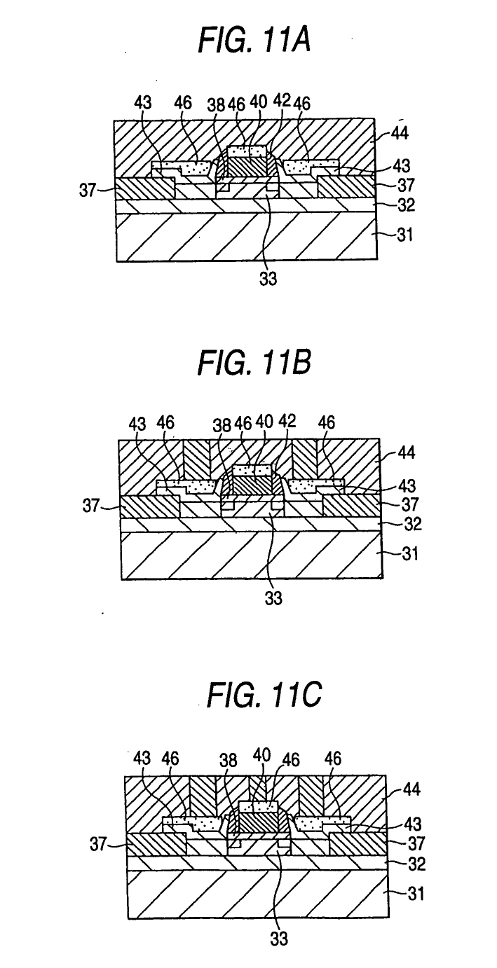

After, as required, transformed into the silicide, there are successively conducted NSG deposition (FIG. 11A), source/drain contact photoetching (FIG. 11B) and gate contact photoetching (FIG. 11C) to thereby fabricate the full depletion SOI-MOS transistor of the present invention.

The above method of fabrication enhances the throughput since the polysilicon layers A and B are formed without relying upon the epitaxial growth method.

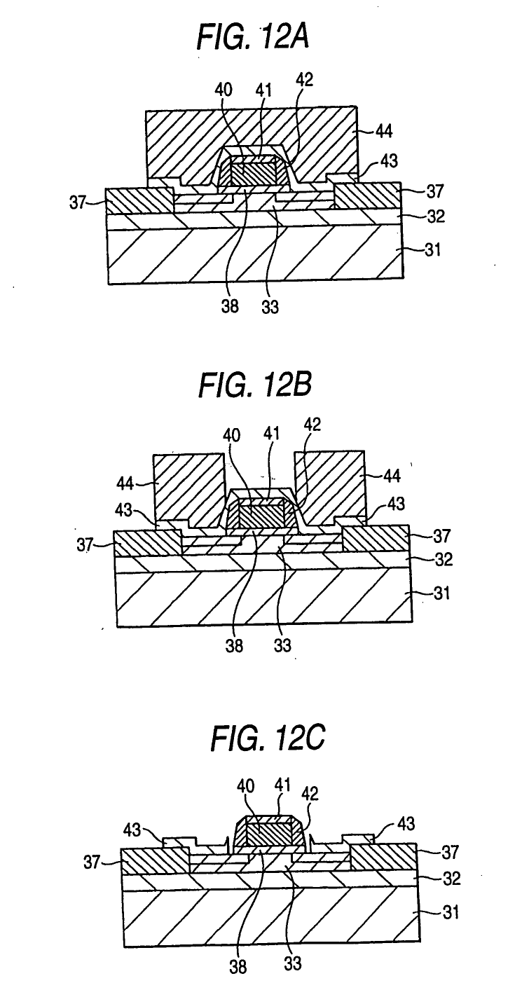

According to another method of fabrication of the invention, the polysilicon layer B on the gate can be partly exposed by employing the steps of FIG. 12 instead of the steps shown in FIGS. 7C and 8.

That is, as shown in FIG. 12A, the resist 44 that is formed to be patterned and, then, as shown in FIG. 12B, the resist 44 is removed by patterning in a manner that the gate is partly exposed. Thereafter, the polysilicon exposed on the gate only is selectively removed by polysilicon etching, and the resist 44 remaining on the polysilicon layer 43 is removed (FIG. 12C).

In the steps shown in FIGS. 7C and 8, the polysilicon on the isolation portion is removed in a self-aligned manner making, however, it difficult to control the thickness of the film in etching the resist. In the steps shown in FIG. 12, on the other hand, the ordinary patterning is conducted, and the resist etching needs not be controlled if attention is given to the alignment with the gate. As a result, it is allowed to conduct the processings under easier conditions and to improve the throughput.

As another constitution, polysilicon of the exposed polysilicon layer B and polysilicon of the polysilicon layer B on the isolating portion may be removed at one time after the step of removing the resist has been finished, so that the polysilicon layer B on the gate is partly exposed.

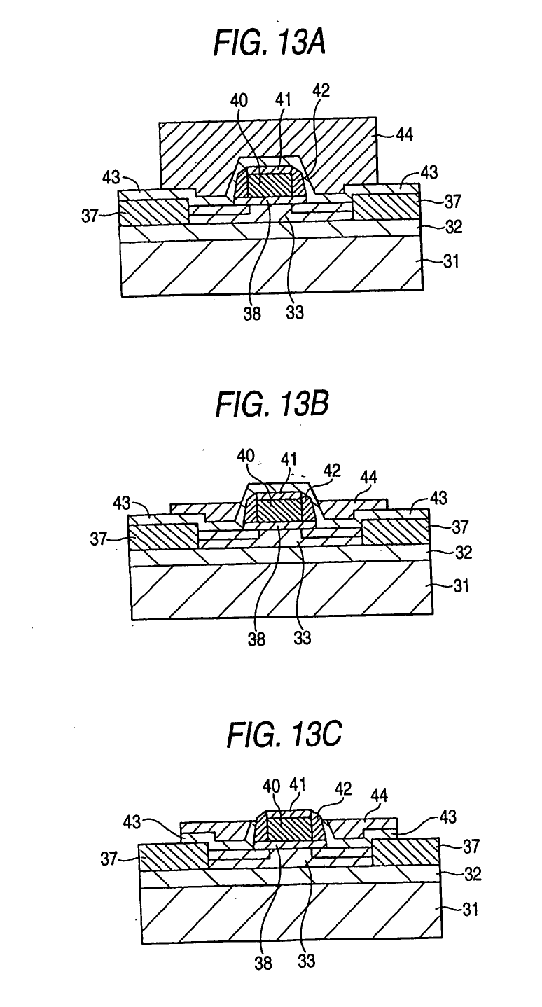

Namely, instead of conducting the steps shown in FIG. 7C and FIG. 8, it is also allowable to pattern the resist 44 only as shown in FIG. 13A and, then, etch the resist so that the polysilicon layer B on the gate is partly exposed (FIG. 13B), and remove polysilicon of the exposed polysilicon layer 43 on the gate as well as polysilicon of the polysilicon layer on the isolation portion (exposed portion on the isolation oxide film 37) at one time (FIG. 13C). These steps can also be adapted to the steps of FIG. 12.

It is, then, made possible to decrease the number of steps of etching the polysilicon by one and to more quickly fabricate the full depletion SOI transistor of the invention offering further improved throughput.

Though the above description has dealt with the steps in relation to nMOS only, the gate and elevated-source/drain portions of pMOS, too, can also be simultaneously fabricated. The steps that differ depending upon the nMOS and the pMOS, such as source/drain implantation and the like, can be separated into those for the nMOS and the pMOS relying upon the ordinary photoetching method. Therefore, this fabrication method can be applied to the CMOS.

According to the present invention, there is provided a full depletion SOI-MOS transistor which improves the throughput, suppresses the short-channel effect and gives a low source-drain resistance, and a method of fabricating the same.

What is claimed is:

1. A full depletion SOI-MOS transistor comprising:
a substrate having a main surface;
a buried oxide layer formed on the main surface of the substrate;
a thin silicon layer formed on the buried oxide layer, the thin silicon layer including a channel region and a source/drain region;
an isolation layer formed on the buried oxide layer, the isolation layer surrounding the thin silicon layer;
a gate insulation layer formed on the channel region of the thin silicon layer;
a gate electrode formed on the gate insulation layer; and
a polysilicon layer formed on the source/drain region of the thin silicon layer.

2. A full depletion SOI-MOS transistor according to claim 1, further comprising a sidewall formed on the gate insulation layer, wherein the sidewall surrounds the gate electrode.

3. A full depletion SOI-MOS transistor according to claim 1, wherein the polysilicon layer extends on the isolation layer.

4. A full depletion SOI-MOS transistor according to claim 2, wherein the polysilicon layer extends on the sidewall.

5. A full depletion SOI-MOS transistor according to claim 1, wherein a thickness of the thin silicon layer is about 20 to 80 percent of a total thickness of the thin silicon layer and the polysilicon layer.

6. A full depletion SOI-MOS transistor according to claim 1, wherein a thickness of the thin silicon layer is about less than 35 nm.

7. A full depletion SOI-MOS transistor comprising:
a substrate having a main surface;
a buried oxide layer formed on the main surface of the substrate;
a thin silicon layer formed on the buried oxide layer, the thin silicon layer including a channel region and a source/drain region;
an isolation layer formed on the buried oxide layer, the isolation layer surrounding the thin silicon layer;
a gate insulation layer formed on the channel region of the thin silicon layer;
a gate electrode formed on the gate insulation layer; and
a silicide layer formed on the source/drain region of the thin silicon layer and the gate electrode.

8. A full depletion SOI-MOS transistor according to claim 7, further comprising a sidewall formed on the gate insulation layer, wherein the sidewall surrounds the gate electrode and silicide layer formed thereon.

9. A full depletion SOI-MOS transistor according to claim 7, wherein the silicide layer formed on the source/drain region extends on the isolation layer.

10. A full depletion SOI-MOS transistor according to claim 8, wherein the silicide layer formed on the source/drain region extends on the sidewall.

11. A full depletion SOI-MOS transistor according to claim 7, wherein a thickness of the thin silicon layer is about 20 to 80 percent of a total thickness of the thin silicon layer and the silicide layer formed on the source/drain region.

12. A full depletion SOI-MOS transistor according to claim 7, wherein a thickness of the thin silicon layer is about less than 35 nm.

13. A full depletion SOI-MOS transistor comprising:
a substrate having a main surface;
a BOX layer formed on the main surface of the substrate;
an SOI layer formed on the BOX layer, the SOI layer including a channel region and a source/drain region;
an isolation layer formed on the BOX layer, the isolation layer surrounding the SOI layer;
a gate insulation layer formed on the channel region of the SOI layer;
a gate electrode formed on the gate insulation layer; and
a high mobility conductive layer formed on the source/drain region of the thin silicon layer, the high mobility conductive layer containing polysilicon.

14. A full depletion SOI-MOS transistor according to claim 13, further comprising a sidewall formed on the gate insulation layer, wherein the sidewall surrounds the gate electrode.

15. A full depletion SOI-MOS transistor according to claim 13, wherein the high mobility conductive layer extends on the isolation layer.

16. A full depletion SOI-MOS transistor according to claim 14, wherein the high mobility conductive layer extends on the sidewall.

17. A full depletion SOI-MOS transistor according to claim 13, wherein a thickness of the SOI layer is about 20 to 80 percent of a total thickness of the SOI layer and the high mobility conductive layer.

18. A full depletion SOI-MOS transistor according to claim 13, wherein a thickness of the SOI layer is about less than 35 nm.

19. A full depletion SOI-MOS transistor according to claim 13, wherein the high mobility conductive layer contains silicide.

20. A full depletion SOI-MOS transistor according to claim 19, wherein the high mobility conductive layer is formed on the gate electrode.
